(19) United States
(12) Patent Application Publication
(10) Pub. No.: US 2019/0287728 A1
(43) Pub. Date: Sep. 19, 2019

(54) COMPOSITE PROTECTION ELEMENT AND ELECTRONIC DEVICE INCLUDING SAME

(71) Applicant: MODA-INNOCHIPS CO., LTD., Ansan-Si, Gyeonggi-Do (KR)

(72) Inventors: Seung Hun CHO, Siheung-Si, Gyeonggi-Do (KR); Dong Suk LEE, Incheon (KR); Jung Hun LEE, Ansan-Si, Gyeonggi-Do (KR)

(21) Appl. No.: 16/464,262

(22) PCT Filed: Nov. 13, 2017
(86) PCT No.: PCT/KR2017/012810

§ 371 Date: May 24, 2019

(30) Foreign Application Priority Data
Dec. 6, 2016 (KR) 10-2016-0165265

(51) Int. Cl. H01G 4/40; H05K 9/00; H01G 4/01; H01G 4/12; H01G 4/10

(52) U.S. Cl. CPC H01G 4/40; H05K 9/0067; H01G 4/01; H01G 4/232; H01G 4/1218; H01G 4/10; H01G 4/1227

(57) ABSTRACT

The present disclosure provides a complex protection device including: a laminate in which a plurality of sheets are laminated; a plurality of internal electrodes formed inside the laminate; an overvoltage protection part formed on at least a portion of the sheets; and an external electrode provided outside the laminate and connected to the internal electrode and the overvoltage protection part, wherein at least a portion of the plurality of sheets has a dielectric constant different from the other sheets.

### TECHNICAL FIELD

The present disclosure herein relates to a complex protection device, and more particularly, to a complex protection device which is provided to various types of electronic apparatuses and is capable of protecting an electronic apparatus or a user from voltage or current.

### BACKGROUND

Various components are integrated in an electronic apparatus, such as a smartphone having multi-functions, according to the functions. In addition, electronic apparatuses are provided with antennas capable of receiving different frequency bands for each function, such as wireless LANs, Bluetooth, global positioning systems, and the like with various frequency bands, and some of these antennas may be installed as embedded antennas in a case constituting the electronic apparatuses. Accordingly, a contactor is installed for electrical connection between the antenna installed on a case and the internal circuit of the electronic apparatus.

Meanwhile, as high-grade image and durability of smartphones have recently been emphasized, terminals using metal materials are being widely spread. That is, the spread of smartphones has been increasing which have peripheries made of metal or other portions made of metal excluding a front screen display part.

However, when using a smartphone while charging the smartphone having a metal case with a non-genuine charger, an electric shock accident can be caused. That is, a shock current is caused by charging using a non-genuine charger or a defective charger in which an overcurrent protection circuit is not included or low-quality elements are used, and such a shock current is conducted to the ground terminal of a smartphone and further conducted to a metal case, and thus, a user touching the metal case may get shocked.

Accordingly, a component is being demanded which is capable of preventing breakage of an internal circuit due to electrostatic electricity and an electric shock accident of a user.

The present disclosure herein provides a complex protection device and an electronic apparatus having the same which are provided to an electronic apparatus such as a smartphone and are capable of protecting the electronic apparatus or a user.

The present disclosure herein also provides a complex protection device and an electronic apparatus which are not electrically broken down by an overvoltage such as an electrostatic discharge (ESD).

The present disclosure herein also provides a complex protection device and an electronic apparatus which are capable of adjusting parasitic capacitance and preventing performance degradation in an electronic apparatus due to the parasitic capacitance.

### RELATED ART DOCUMENT

Korean Patent No. 10-0876206

### SUMMARY

In accordance with an exemplary embodiment, a complex protection device includes: a laminate in which a plurality of sheets are laminated; a plurality of internal electrodes formed inside the laminate; an overvoltage protection part formed on at least a portion of the sheets; and external electrodes provided outside the laminate and connected to the internal electrodes and the overvoltage protection part, wherein at least a portion of the plurality of sheets has a dielectric constant different from other sheets.

The overvoltage protection part may include: at least two discharge electrodes; and at least one overvoltage protection layer provided between the discharge electrodes.

The overvoltage protection layer may include at least one among a porous insulating material, a conductive material, and a void.

The discharge electrodes and internal electrodes adjacent thereto may be connected to a same external electrode.

The discharge electrodes and the internal electrodes adjacent thereto may be connected to different external electrodes.

At least one of the plurality of internal electrodes may be formed in a length different form the other internal electrodes.

The external electrodes may extend to at least any one of a lowermost layer and an uppermost layer of the laminate and may partially overlap outermost internal electrodes.

The outermost internal electrodes may each be formed such that a region overlapping the external electrode is formed to have a width larger than remaining regions.

Dielectric constants of the sheets provided between the external electrodes and the outermost internal electrodes may be lower than dielectric constants of other sheets.

The dielectric constants of the sheets provided between the external electrodes and the outermost internal electrodes may be at most approximately 100 and dielectric constants of other sheets are at least approximately 500.

A sheet provided between the external electrodes and the outermost internal electrodes may have a lower Ba or Ti content than the remaining sheets.

A sheet provided between the external electrodes and the outermost internal electrodes may have a lower Nd or Bi content than the remaining sheets.

In accordance with another exemplary embodiment, an electronic apparatus includes a complex protection device provided between a conductor contactable to a user and an internal circuit and configured to block a shock voltage and bypass an overvoltage.

### Advantageous Effects

A complex protection device in accordance with exemplary embodiments is provided between a metal case and an internal circuit of an electronic apparatus, blocks a shock voltage, and bypasses an overvoltage such as an ESD to a ground terminal. That is, the complex protection device is provided with a protection part for protecting the internal circuit by blocking a shock voltage leaking from the internal circuit and protecting an internal overvoltage, and prevents the overvoltage from being introduced into the electronic apparatus. Accordingly, the electronic apparatus and a user may be protected from voltage and current.

In addition, external electrodes are formed to overlap at least a portion of internal electrodes and overlapping areas are adjusted, so that the capacitance of the complex protection device may be adjusted. In addition, the dielectric constants of the sheets between the external electrodes and the internal electrodes are decreased to be smaller than the dielectric constants of the other sheets, so that the distribution of parasitic capacitance may be reduced, and thus, the performance degradation of the electronic apparatus such as performance degradation of an antenna due to the parasitic capacitance may be prevented.

Meanwhile, the internal electrodes adjacent to discharge electrodes of a protection part may be connected to the same external electrode, and thus, an overvoltage may be prevented from being introduced into the internal circuit even when the sheet is electrically broken down.

### BRIEF DESCRIPTION OF THE DRAWINGS

FIGS. 1 and 2 are a perspective view and a plan view of a complex protection device in accordance with an exemplary embodiment.

FIGS. 3 to 5 are a cross-sectional photograph and partially enlarged photographs of a complex protection device in accordance with an exemplary embodiment.

FIGS. 6 to 8 are cross-sectional views of protective layers that constitute a complex protection device in accordance with an exemplary embodiment.

FIG. 9 is a cross-sectional view of a complex protection device in accordance with an exemplary embodiment.

FIGS. 10 to 11 are equivalent circuit diagrams of complex protection devices in accordance with exemplary embodiments.

FIGS. 12 to 13 are cross-sectional views of complex protection devices in accordance with modified examples of exemplary embodiments.

### DETAILED DESCRIPTION

Hereinafter, exemplary embodiments will be described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

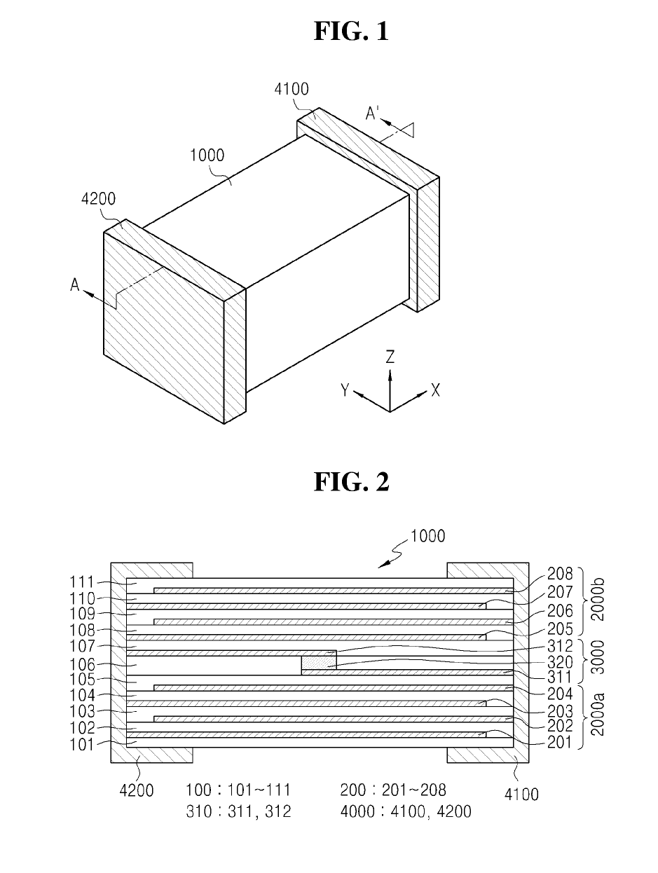

FIG. 1 is a perspective view of and FIG. 2 is a plan view of a complex protection device in accordance with an exemplary embodiment.

Referring to FIGS. 1 and 2, a complex protection device in accordance with an exemplary embodiment may include: a laminate 1000 in which a plurality of sheets 100 (101 to 111) are laminated; one or more capacitor parts 2000 (2000a, 2000b) provided inside the laminate 1000 and provided with a plurality of internal electrodes 200 (201 to 208); and a protection part 3000 provided with at least one discharge electrode 310 (311, 312) and a protective layer 320 and configured to protect an overvoltage such as an ESD. For example, the first and second capacitor parts 2000a and 2000b may be provided inside the laminate 1000, and the protection part 300 may be provided therebetween. That is, the first capacitor part 2000a, the protection part 3000, and the second capacitor part 2000b are stacked inside the laminate 1000, so that a complex protection device may be implemented. In addition, external electrodes 4000 (4100, 4200) may further be included which are formed on two surfaces facing each other in the laminate 1000 and are connected to the capacitor part 2000 and the protection part 3000. Of course, the complex protection device may include at least one capacitor part 2000 and at least one protection part 3000. That is, the capacitor part 2000 may be provided to at least one of a lower side or an upper side of the protection part 3000, and at least one capacitor part 2000 may also be provided to upper sides and lower sides of two or more protection parts 3000 separated from each other. Such a complex protection device is provided to a conductor and an internal circuit which may be brought into contact with a user of an electronic apparatus, for example, provided between a metal case and a PCB, blocks a shock voltage, bypasses an ESD voltage, and thus may continuously block the shock voltage since insulation is not broken down by the ESD.

1. 1. Laminate

The laminate 1000 may be provided in an approximate hexahedron shape. That is, the laminate 1000 may be provided in an approximate hexahedral shape which has predetermined length and width respectively in one (for example, X-direction) and the other (for example, Y-direction) directions horizontally perpendicular to each other and which has a predetermined height in the vertical direction (for example, Z-direction). That is, when the X-direction is the direction of forming the external electrodes 4000, the direction horizontally perpendicular to the X-direction may be set as the Y-direction, and the vertical direction may be set as Z-direction. Here, the length in the X-direction may be larger than the width in the Y-direction and the height in the Z-direction, and the width in the Y-direction may be the same as or different from the height in the Z-direction. When the width (Y-direction) and the height (Z-direction) are different, the width may be smaller or larger than the height. For example, the ratio of the length, width, and height may be approximately 2 to 5:1.0:0.3 to 1. That is, with respect to the width, the length may be approximately two to five times larger than the width, and the height may be approximately 0.3 to 1 times the width. However, such sizes in the X-, Y-, and Z-directions may be variously changed, for example, according to the internal structure of an electronic apparatus connected with the complex protection device and the shape of the complex protection device.

The laminate 1000 may be formed by laminating a plurality of sheets 100 (101 to 111). That is, the laminate 1000 may be formed by laminating a plurality of sheets 100 each having a predetermined length in the X-direction, a predetermined width in the Y-direction, and a predetermined thickness in the Z-direction. Thus, the length and the width of the laminate 1000 may be determined by the length and the width of the sheet 100, and the height of the laminate 1000 may be determined by the number of lamination of the sheet 100. Meanwhile, the plurality of sheets 100 constituting the laminate 1000 may be formed by using dielectric materials such as MLCC, LTCC and HTCC. Here, in the MLCC dielectric material, at least one of Bi₂O₃, SiO₂, CuO, MgO or ZnO may be added with respect to a main component which is at least either of BaTiO₃ or NdTiO₃, and the LTCC dielectric material may include Al₂O₃, SiO₂, or a glass material. In addition, the sheet 100 may be formed by a material including one or more of BaTiO₃, NdTiO₃, Bi₂O₃, BaCO₃, TiO₂, Nd₂O₃, SiO₂, CuO, MgO, ZnO or Al₂O₃ aside from MLCC, LTCC and HTCC. In addition, the sheet 100 may also be formed by a material such as Pr-based, Bi-based, or ST-based ceramic material, having a varistor characteristic aside from the above-mentioned materials. Of course, the sheet 100 may also be formed by mixing MLCC, LTCC and HTCC and a material having a varistor characteristic. For example, the sheet 100 may include BaTiO₃, NdTiO₃, Bi₂O₃, ZnO, TiO₂, SiO₂, Al₂O₃ or B₂O₃ and the dielectric constant may be adjusted by adjusting the contents of these materials. Thus, the sheet 100 may have a predetermined dielectric constant of, for example, approximately 5-20,000, and favorably approximately 7-4,000, and more favorably approximately 100-3,000, according to a material. For example, the sheet 100 may include BaTiO₃, NdTiO₃, Bi₂O₃, ZnO, TiO₂, SiO₂, Al₂O₃ or B₂O₃ and the dielectric constant may be raised by increasing the content of BaTiO₃, and may be lowered by increasing the contents of NdTiO₃ and SiO₂. Meanwhile, at least one of the sheets 110 may have a dielectric constant different from the others. For example, the outermost sheets, that is, the first and 11th sheet 101 and 111 respectively located at the lowermost layer and the uppermost layer in the vertical direction may have different dielectric constants different from those of the other sheets provided therebetween, that is, the second to 10th sheets 102 to 110. That is, the dielectric constants of the first and 11th sheets 101 and 111 may be lower than those of the second to 10th sheets 102 to 110. For example, the dielectric constants of the first and 11th sheets 101 and 111 may at most 100, and the dielectric constants of the second to 10th sheets 102 to 110 may be at least 500. For example, the dielectric constants of the first and 11th sheets 101 and 111 may be at most approximately 5-100, and the dielectric constants of the second to 10th sheets 102 to 111 may be at least approximately 500-3,000. As such, in order to differentiate the dielectric constants of the sheets 100, the contents of the compositions for forming the sheets may be adjusted. For example, in the first to 11th sheet 101 to 111, which may include BaTiO₃, NdTiO₃, Bi₂O₃, ZnO, TiO₂, SiO₂, Al₂O₃ or B₂O₃, the first and 11th sheets 101 and 111 may be formed to have the dielectric constants of at most approximately 100 by increasing the contents of NdTiO₃ or SiO₂ and decreasing the content of BaTiO₃, and the second to 10th sheets may be formed to have the dielectric constants of at least approximately 500 by increasing the contents of BaTiO₃ and decreasing the content of NdTiO₃ or SiO₂. That is, the first and 11th sheet 101 and 111 may be allowed to have the dielectric constants of at most approximately 100 by increasing the content of NdTiO₃ or SiO₂ and decreasing the content of BaTiO₃ compared to the second to 10th sheets 102 to 110. In comparison, the second to 10th sheets 102 to 110 may be allowed to have the dielectric constant of at least approximately 500 by increasing the content of BaTiO₃ and decreasing the content of NdTiO₃ or SiO₂ compared to the first and 11th sheets 101 and 111. As such, parasitic capacitance may be reduced by lowering the dielectric constants of the outermost sheets. Meanwhile, among the second to 10th sheets 102 to 110, the sheets adjacent to the first and 11th sheets, for example, the second and 10th sheets 102 and 110 may have the dielectric constants lower than those of the other sheets 103 to 109 therebetween. In addition, the closer to a central portion from the first and 11th sheets, the higher the dielectric constants of the sheets may be. This is because the composition of the first and 11th sheets 101 and 111 are diffused to the central portion of the laminate 1000.

In addition, all of the plurality of sheets 100 may be formed in the same thickness, and at least any one may be formed to be thicker or thinner than the others. For example, the sheets of the protection part 3000 may be formed in different thicknesses than those of the capacitor part 2000, and the sheets formed between the protection part 3000 and the capacitor part 2000 may be formed in different thicknesses than those of other sheets. For example, the sheets between the protection part 3000 and the capacitor part 2000, that is, the fifth and seventh sheets 105 and 107 may be formed in a thickness which is thinner than or equal to that of the sheet of the protection part 3000, that is, the sixth sheet 106, or may be formed in thickness which is thinner than or equal to those of the sheets 102 to 104 and 108 to 110 between the internal electrodes of the capacitor part 2000. That is, the distance between the protection part 3000 and the capacitor part 2000 may be formed to be smaller than or equal to the distance between the internal electrodes of the capacitor part 2000, or be smaller than or equal to the thickness of the protection part 3000. Of course, the sheets 102 to 104 and 108 to 110 of the capacitor part 2000 may be formed in the same thickness, or any one thereof may be thinner or thicker than another. Meanwhile, the plurality of sheets 100 may be formed in a thickness of, for example, approximately 1 μm-4,000 μm or in a thickness of at most approximately 3,000 μm. That is, according to the thickness of the laminate 1000, the thickness of each of the sheets 100 may be approximately 1 μm-4,000 μm, and favorably approximately 5 μm-300 μm. In addition, according to the size of the complex protection device, the thickness, the number of lamination, or the like of the sheet 100 may be adjusted. That is, when applied to a complex protection device having a small size, the sheet 100 may be formed in a small thickness, and when applied to a complex protection device having a large size, the sheet may be formed in a large thickness. In addition, when the same number of sheets 100 are laminated, the smaller the height of a complex protection device having a small size, the smaller the thicknesses of the sheets may be, and the larger the size of the complex protection device, the larger the thicknesses of the sheets may be. Of course, a thin sheet may be applied to a complex protection device having a large size, and in this case, the number of lamination of the sheets increases. In this case, the sheet 100 may be formed in a thickness that is not broken down when applying an ESD thereto. That is, even when the sheets 100 are formed by different numbers of lamination or different thicknesses, at least one sheet may be formed in a thickness which is not broken down by repeated application of an ESD.

In addition, the laminate 1000 may further include a lower cover layer (not shown) and an upper cover layer (not shown) which are respectively provided on and under the capacitor part 2000. That is, the laminate 1000 may include the lower cover layer and the upper cover layer respectively provided to the lowermost layer and the uppermost layer. Of course, the sheet of the lowermost layer, that is, the first sheet 101 may also function as the lower cover layer and the sheet of the uppermost layer, that is, the 11th sheet 111 may also function as the upper cover layer. The lower and upper cover layers which are separately provided from the sheet 100 may be formed in the same thickness. However, the upper and lower cover layers may also be formed in different thicknesses, for example, the upper cover layer may be formed to be thicker than the lower cover layer. Here, the lower and upper cover layers may be provided by laminating a plurality of magnetic sheets. In addition, a non-magnetic sheet, such as a glass sheet, may further be provided on the outer surfaces of the lower and upper cover layers, that is, the lower surface and upper surface of the laminate 1000. However, the lower and upper cover layers may also be formed in a glass sheet, and the surfaces of the laminate 1000 may be coated with a polymer glass material. Meanwhile, the lower and upper cover layers may have larger thicknesses than each of the sheets 100. That is, the cover layers may have thicknesses larger than the thickness of a single sheet. Thus, when the sheets of the lowermost layer and the uppermost layer, that is, the first and 11th sheets 101 and 111, function as the lower and upper cover layers, the first and 11th sheets may be formed to be thicker than each of the sheets 102 to 110 therebetween.

2. 2. Capacitor Part

At least one capacitor part 2000 (2000a and 2000b) is formed inside the laminate 1000. For example, the first and second capacitor parts 2000a and 2000b may be provided on and under the protection part 3000 with the protection part therebetween. However, the first and second capacitor parts 2000a and 2000b are referred to as such because a plurality of internal electrodes 200 are formed to be divided with the protection part 3000 therebetween, and the plurality of internal electrodes 200 which function as capacitors may be formed inside the laminate 1000.

The capacitor parts 2000 are provided respectively on and under the protection part, and may include at least two or more internal electrodes and at least two or more sheets provided therebetween. For example, the first capacitor part 2000a may include first to fourth sheets 101 to 104 and first to fourth internal electrodes 201 to 204 which are respectively formed on the first to fourth sheets 101 to 104. In addition, the second capacitor part 2000b may include seventh to 10th sheets 107 to 110 and fifth to eighth internal electrodes 205 to 208 which are respectively formed on the seventh to 10th sheets 107 to 110. Here, the internal electrodes 200 (201 to 208) may be formed in respective thicknesses of, for example, approximately 1 μm to 10 μm. In addition, the plurality of internal electrodes 200 may be formed to have one side connected to external electrodes 4000 (4100, 4200) formed to face each other in the X-direction, and the other side spaced apart from the external electrodes. For example, the first, third, fifth, and seventh internal electrodes 201, 203, 205 and 207 are formed to have respective predetermined area on the first, third, seventh, and ninth sheets 101, 103, 107 and 109, and formed to have one side connected to the second external electrode 4200 and the other side to be spaced apart from the first external electrode 4100. In addition, the second, fourth, sixth, and eighth internal electrodes 202, 204, 206 and 208 are formed to have respective predetermined area on the second, fourth, eighth, and 10th sheets 102, 104, 108 and 110, and formed to have one side connected to the first external electrode 4100 and the other side to be spaced apart from the second external electrode 4200. That is, the plurality of internal electrodes 200 are formed to be alternately connected to any one of the external electrodes 4000, and to overlap a predetermined region with the sheets 102 to 104 and 108 to 110 therebetween. In addition, the internal electrode 200 may be formed to have a length in the X-direction and a width in the Y-direction which are smaller than those of the laminate 1000. That is, the internal electrode 200 may be formed to have the length and width smaller than those of the sheet 100. For example, the internal electrode 200 may be formed to have a length of approximately 10% to 90% of the length and a width of approximately 10% to 90% of those of the laminate 1000 or the sheet 100. In addition, the internal electrode 200 may be formed to have an area of approximately 10% to 90% of each of the sheets 100. Meanwhile, the plurality of internal electrodes 200 may each be formed in various shapes, such as a square, a rectangle, and a spiral shape having a predetermined pattern shape, a predetermined width and a predetermined interval. The capacitor part 2000 has capacitance formed between the internal electrodes 200, and the capacitance may be adjusted according to overlapping areas of the internal electrodes 200 and the thicknesses of the sheets 100. Meanwhile, the capacitor part 2000 may further be provided with one or more internal electrodes formed therein aside from the first to eighth internal electrodes 201 to 208, and at least one sheet may further be formed in which at least one internal electrode is formed. In addition, each of the first and second capacitor parts 2000a and 2000b may also have two internal electrodes formed therein. That is, in the present exemplary embodiment, each of the first and second capacitors 2000a and 2000b are exemplarily described to have four internal electrodes formed therein, but the internal electrodes may be formed in plurality to be two or more.

The internal electrodes 200 may be formed of conductive materials, for example, may be formed of a metal or a metal alloy including any one or more among Al, Ag, Au, Pt, Pd, Ni, and Cu. In case of the alloy, for example, an alloy of Ag and Pd may be used. Meanwhile, aluminum oxide (Al₂O₃) may be formed on a surface while firing Al, and the internal portion may maintain Al. That is, when forming Al on a sheet, Al comes into contact with air, and the surface of Al is oxidized in a firing process, so that Al₂O₃ is formed and the internal portion maintains Al as it is. Thus, the internal electrode 200 may be formed in Al having the surface coated with Al₂O₃ which is a thin porous insulating layer. Of course, aside from Al, various metals may be used in which an insulating layer, favorably a porous insulating layer is formed on a surface. Meanwhile, the thickness of at least one region is small or at least one region is removed, so that the internal electrode 200 may be formed to expose a sheet. However, even though at least one region of the internal electrode 200 is small or at least one region is removed, the overall connected state is maintained. Therefore, there is no problem occurring in electrical conductivity.

Meanwhile, the internal electrodes 201 to 204 of the first capacitor part 2000a and the internal electrodes 205 to 208 of the second capacitor part 2000b may be formed in the same shape and the same area, and the overlapping area may also be the same. However, the first internal electrode 201 and the eighth internal electrode 208 may overlap the external electrode 4000, and the first and eighth electrodes 201 and 208 may be formed to be longer than the other electrodes 202 to 207. That is, the first and eighth electrodes 201 and 208 are formed such that an end portions thereof partially overlap the respective first and second external electrodes 4100 and 4200 and parasitic capacitance is formed therebetween. Therefore, the first and eighth electrodes 201 and 208 may be formed to be, for example, approximately 10% longer than the other internal electrodes 201 to 207. In addition, the first and eighth electrodes 201 and 208 may each be formed such that a region overlapping the external electrode 400 is formed to be larger than the other regions. For example, the first and eighth electrodes 201 and 208 may each be formed such that a region overlapping the external electrode 4000 or a region adjacent thereto may be approximately 10% wider than non-overlapping regions. At this point, the regions that do not overlap the external electrode 4000 in the first and eighth electrodes 201 and 208 may have the same width as the other internal electrodes 202 to 209. Meanwhile, the sheets 101 to 104 of the first capacitor part 2000a and the sheets 107 to 110 of the second capacitor part 2000b may have the same thickness. At this point, when the first sheet 101 functions as the lower cover layer, the first sheet 101 may be formed to be thicker than the other sheets. Thus, the first and second capacitor parts 2000a and 2000b may have the same capacitance. However, the capacitance of the first and second capacitor parts 2000a and 2000b may be different, and in this case, at least any one among the areas of the internal electrodes, the overlapping areas of the internal electrodes, and the thicknesses of the sheets may be different from each other. In addition, the internal electrodes 201 to 208 of the capacitor part 2000 may be formed to be longer than the discharge electrodes 310 of the protection part 3000, and the areas thereof may also be formed to be larger.

3. 3. Protection Part

The protection part 3000 may include at least two discharge electrodes 310 (311 and 312) formed to be vertically separated and at least one protective layer 320 provided between the discharge electrodes 310. For example, the protection part 3000 may include: fifth and sixth sheets 105 and 106; first and second discharge electrode 311 and 312 which are respectively formed on the fifth and sixth sheets 105 and 106; and a protective layer 320 formed to pass through the sixth sheet 106. Here, the protective layer 320 may be formed to be at least partially connected to the first and second discharge electrodes 311 and 312. The first and second discharge electrodes 311 and 312 may be formed in the same thickness as the internal electrodes 200 of the capacitor part 2000. For example, the first and second discharge electrodes 311 and 312 may be formed in a thickness of approximately 1 μm to 10 μm. However, the first and second discharge electrodes 311 and 312 may be formed to be thinner or thicker than the internal electrodes 200 of the capacitor part 2000. The first discharge electrode 311 is formed on the fifth sheet 105 so as to be connected to the first external electrode 4100, and connected such that an end portion thereof is connected to the protective layer 320. The second discharge electrode 312 is formed on the sixth sheet 106 so as to be connected to the second external electrode 4200, and connected such that an end portion thereof is connected to the protective layer 320.

Here, the discharge electrodes 311 and 312 are formed to be connected to the respective adjacent internal electrodes 200 and the same respective external electrodes 4000. That is, the first discharge electrode 311 is connected to the adjacent fourth internal electrode 204 and the first external electrode 4100, and the second discharge electrode 312 is connected to the adjacent fifth electrode 205 and the second external electrode 4200. As such, the discharge electrode 310 and the internal electrode 200 adjacent thereto are connected to the same external electrode 4000, so that even when the insulating sheet 100 is degraded, that is, is broken down, an ESD voltage is not applied to the inside of an electronic apparatus. That is, when the discharge electrode 310 and the internal electrode 200 adjacent thereto are connected to the different external electrodes 4000, the ESD voltage applied through one external electrode 4000 may flow to the other external electrodes 4000 through the discharge electrode 310 and the adjacent internal electrode 200 when the insulating sheet 100 is broken down. For example, when the first discharge electrode 311 is connected to the first external electrode 4100, and the fourth electrode 204 adjacent thereto is connected to the second external electrode 4200, and when the insulating sheet 100 is broken down, a conduction path is also formed between the first discharge electrode 311 and the fourth electrode 204, and an ESD voltage applied through the first external electrode 4100 flows, via the first external electrode 4100, to the first discharge electrode 311, the broken down fifth insulating sheet 105, and the second internal electrode 202, and may thus be applied to an internal circuit via the second external electrode 4200. In order to solve such a problem, the thickness of the insulating sheet 100 may be formed to be large, but in this case, there is a problem in that the size of an electric shock prevention device increases. However, the discharge electrode 310 and the internal electrode 200 adjacent thereto are connected to the same external electrode 4000, so that even when the insulating sheet 100 is broken down, an ESD voltage is not applied to the inside of an electronic apparatus. In addition, the application of the ESD voltage may be prevented even without forming the insulating sheet 100 to have a large thickness.

Meanwhile, the regions to be in contact with the protective layer 320 of the first and second discharge electrodes 311 and 312 may be formed to have sizes equal to or smaller than the sizes of the protective layers 320. In addition, the first and second discharge electrodes 311 and 312 may also be formed to completely overlap each other without departing from the protective layer 320. That is, the edges of the first and second discharge electrodes 311 and 312 may form vertical components together with the edge of the protective layer 320. Of course, the first and second discharge electrodes 311 and 312 may be formed to overlap a portion of the protective layer 320 without departing from the protective layer 320. For example, the first and second discharge electrodes 311 and 312 may be formed to overlap approximately 10% to 100% of the horizontal area of the protective layer 320. That is, the first and second discharge electrodes 311 and 312 are not formed to depart from the protective layer 320. Meanwhile, one region to be in contact with the protective layer 320 in the first and second discharge electrodes 311 and 312 may be formed to be larger than the region which is not in contact with the protective layer 320.

The protective layer 320 may be connected to a predetermined region of the sixth sheet 106, for example, may be formed on a central portion and connected to the first and second discharge electrodes 311 and 312. At this point, the protective layer 320 may be formed to at least partially overlap the first and second discharge electrodes 311 and 312. At this point, the protective layer 320 may be formed such that approximately 10% to 100% of the horizontal areas thereof overlap the first and second discharge electrodes 311 and 312. The protective layer 320 may be formed such that a through-hole with a predetermined size is formed on a predetermined region of the sixth sheet 106, for example, at a central region, and the through-hole is filled by using a thick film printing process. The protective layer 330 may be formed, for example, in a diameter of approximately 100 μm to 500 μm and a thickness of approximately 10 μm to 50 μm. Here, the smaller the thickness of the protective layer 320, the lower the discharge start voltage. The protective layer 320 may be formed by using a conductive material and an insulating material. For example, the protective layer 320 may be formed by printing a mixed material of conductive ceramic and insulating ceramic on the sixth sheet 106. Meanwhile, the protective layer 320 may also be formed on at least one sheet 100. That is, the protective layer 320 may be formed on at least one sheet, for example, two respective laminated sheets 100 and the discharge electrodes may be formed so as to be spaced apart from each other on the sheets and connected to the protective layer 320. Detailed description on the structure, material, and the like of the protective layer 320 will be provided later.

4. 4. External Electrode

The external electrodes 4000 (4100 and 4200) may be provided on two surfaces facing each other outside the laminate 1000. For example, the external electrodes 4000 may be formed on two surfaces of the laminate 1000 which face each other in the X-direction, that is, in the lengthwise direction. In addition, the external electrodes 4000 may be connected to the internal electrode 200 and the discharge electrode 310 inside the laminate 1000. At this point, any one of the external electrodes 4000 may be connected to an internal circuit, such as a printed circuit board, inside an electronic apparatus, and the other one may be connected to the outside of the electronic apparatus, for example, to a metal case. For example, the first external electrode 4100 may be connected to the internal circuit, and the second external electrode 4200 may be connected to the metal case. In addition, the second external electrode 4200 may be connected to the metal case, for example, via a contactor or a conductive gasket.

The external electrodes 4000 may be formed through various methods. That is, the external electrode 4000 may be formed through an immersing or printing method using a conductive paste or may also be formed through various methods such as deposition, sputtering, plating, or the like. Meanwhile, the external electrode 4000 may be formed to extend to a surface in the Y-direction and Z-direction. That is, the external electrode 4000 may be formed to extend from two surfaces facing each other in the X-direction to four surfaces adjacent to the two surfaces. For example, when immersed in a conductive paste, the external electrodes 4000 may be formed not only on the two surfaces facing each other in the X-direction, but also on the front surface, rear surface in the Y-direction, and the upper surface and lower surface in the Z-direction. In comparison, when forming through a method such as printing, deposition, sputtering, plating, or the like, the external electrodes 4000 may be formed on two surfaces in the X-direction. That is, the external electrodes 4000 may be formed not only one side surface to be mounted on a printed circuit board and the other side surface connected to a metal case, but also on the other regions according to a formation method or a process condition. The external electrodes 4000 may be formed of a metal having electrical conductivity, for example, may be formed of one or more metals selected from the group consisting of gold, silver, platinum, copper, nickel, palladium or an alloy thereof. At this point, at least a portion of the external electrodes 4000 connected to the internal electrodes 200 and the discharge electrode 310, that is, a portion of the external electrodes 4000 which are formed on at least one surface of the laminate 1000 and connected to the internal electrodes 200 and the discharge electrodes 310 may be formed of the same material as the internal electrodes 200 and the discharge electrodes 310. For example, when the internal electrodes 200 and the discharge electrodes 310 are formed by using copper, at least a portion from regions to be in contact with the internal electrodes 200 and the discharge electrodes 310 may be formed by using copper. At this point, copper may be formed through an immersing or printing method using a conductive paste as described above, or be formed through a method of deposition, sputtering, plating, or the like. Favorably, the external electrodes 4000 may be formed by plating. In order to form the external electrodes 4000 through a plating process, a seed layer is formed on the upper and lower surfaces of the laminate 1000, then a plated layer is formed from the seed layer, and thus, the external electrodes may be formed. Here, at least a portion of the external electrodes 4000 connected to the internal electrodes 200 and the discharge electrodes 310 may be the entire side surfaces of the laminate 1000 on which the external electrode 4000 is formed, or may also be partial regions.

In addition, the external electrodes 4000 may further include at least one plated layer. The external electrodes 4000 may be formed in a metal layer of Cu, Ag, or the like, and at least one plated layer may also be formed on the metal layer. For example, the external electrodes 4000 may also be formed such that a copper layer, a Ni plated layer, and Sn or Sn/Ag plated layer are laminated. Of course, in the plated layer, a laminate of a Cu-plated layer and a Sn-plated layer may also be laminated, and a Cu-plated layer, a Ni-plated layer, or Sn-plated layer may also be laminated. In addition, the external electrodes 4000 may be formed by mixing metal powder with multi-component-based glass frit having a main component of, for example, approximately 0.5%-20% of Bi₂O₃ or SiO₂. At this point, the mixture of the glass frit and metal powder is manufactured in a paste form and may be applied to two surfaces of the laminate 1000. As such, by including the glass frit in the external electrodes 4000, tight adhesion of the external electrode 4000 and the laminate 100 may be improved, and a contact reaction of the electrodes inside the laminate 1000 may be improved. In addition, after the conductive paste including glass is applied, at least one plated layer is formed thereon and the external electrodes 4000 may thereby be formed. That is, a metal layer including glass is formed, and at least one plated layer is formed thereon, so that the external electrodes 4000 may be formed. For example, the external electrodes 4000 may be formed such that a layer including glass frit and at least one of Ag or Cu is formed and a Ni-plated layer and a Sn-plated layer may be sequentially formed through electrolytic or electroless plating. At this point, the Sn-plated layer may be formed to have a thickness which is the same as or larger than the Ni-plated layer. Of course, the external electrodes 4000 may also be formed of only one plated layer. That is, the external electrodes 4000 may also be formed by forming at least one layer of plated layer using a plating process at least once without applying the paste. Meanwhile, the external electrodes 4000 may be formed in a thickness of approximately 2 μm-10 μm, the Ni-plated layer may be formed in a thickness of approximately 1 μm-10 μm, and the Sn- or Sn/Ag-plated layer may be formed in a thickness of approximately 2 μm-10 μm.

Meanwhile, the external electrodes 4000 may be formed such that a portion thereof overlap the internal electrode 200 connected to the external electrodes 4000 different from each other. For example, portions of the first external electrode 4100 which extend to lower and upper portions of the laminate 1000 may be formed to overlap predetermined regions of the internal electrodes 200. In addition, portions of the second external electrode 4200 which extend to lower and upper portions of the laminate 1000 may also be formed to overlap predetermined regions of the internal electrodes 200. For example, the portions of the external electrodes 4000 which extend to lower and upper portions of the laminate 1000 may be formed so as to overlap the first and eighth internal electrodes 201 and 208. That is, at least one of the external electrodes 4000 may extend to the upper and lower surfaces of the laminate 1000, and at least one of the extended portions may be formed so as to partially overlap the internal electrodes 200. At this point, the area of the internal electrodes 200 overlapping the external electrode 4000 may be within approximately 1% to 10% of the total area of the internal electrode 200. In addition, in the external electrodes 4000, the area formed on at least one of the upper and lower surfaces of the laminate 1000 through multiple times of processes may be increased.

As such, predetermined parasitic capacitance may be generated between the external electrodes 4000 and the internal electrodes 200 by overlapping the external electrodes 4000 and the internal electrodes 200. For example, the capacitance may be formed between the first and eighth internal electrodes 201 and 208 and the extended portions of the first and second external electrodes 4100 and 4200. Thus, the capacitance of the complex protection device may be adjusted by adjusting the overlapping area of the external electrodes 4000 and the internal electrodes 200. However, since the capacitance of the complex protection device affects the antenna performance inside an electronic apparatus, the distribution of the capacitance of the complex protection device is maintained within approximately 20%, favorably, within approximately 5%. To this end, sheets 100 manufactured by using a material having a high dielectric constant are used. However, the higher the dielectric constants of the sheets 100, the greater the influence of the parasitic capacitance between the internal electrodes 200 and the external electrodes 4000. That is, when the dielectric constants of the first and 11th sheets 101 and 111, which are provided between the internal electrodes 200 and the external electrodes 4000, are high, the parasitic capacitance increases. However, since the dielectric constants of the first and 11th sheets 101 and 111 positioned at the outermost portion are lower than the dielectric constants of the other sheets 102 to 110, the influence of the parasitic capacitance between the internal electrode 200 and the external electrode 4000 may be reduced. That is since the dielectric constants of the first and 11th sheets 101 and 111 are low, the parasitic capacitance between the internal electrodes 200 and the external electrodes 4000 may be reduced.

5. 5. Surface Modified Member

Meanwhile, a surface modified member (not shown) may be formed on at least one surface of the laminate 1000. This surface modified member may be formed by distributing, for example, oxides on the surface of the laminate 1000 before forming the external electrode 4000. Here, the oxides may be spread and distributed on the surface of the laminate 1000 in a crystalline state or a non-crystalline state. The surface modified member may be distributed on the surface of the laminate 1000 before a plating process when forming the external electrode 4000 through a plating process. That is, the surface modified member may be distributed before forming a portion of the external electrode 4000 through a printing process, and may also be distributed before performing a plating process after the printing process. Of course, when the printing process is not performed, the plating process may be performed after distributing the surface modified member. In this case, the surface modified member distributed on the surface may be at least partially melted.

Meanwhile, at least a portion of the surface modified member may be uniformly distributed on the surface of the laminate 1000 in the same size, or at least a portion thereof may also be irregularly distributed in different sizes. In addition, a recessed portion may be formed on at least a portion of the surface of the laminate 1000. That is, a protruding portion is formed by forming the surface modified member, and at least a portion of the region where the surface modified member is not formed is dug, and thus, a recessed portion may be formed. In this case, at least a portion of the surface modified member may be formed to be deeper than the surface of the laminate 1000. That is, a predetermined thickness of the surface modified member is embedded in the laminate 1000 by a predetermined depth, and the remaining thickness may be formed to be higher than the surface of the laminate 1000. In this case, the thickness embedded in the laminate 1000 may be approximately 1/20 to 1 of the average diameter of the oxide particles. That is, all the oxide particles may be embedded into the laminate 1000, or at least a portion thereof may be embedded. Of course, the oxide particles may be formed only on the surface of the laminate 1000. Thus, the oxide particles may be formed in semi spherical shapes on the surface of the laminate 1000, and may also be formed in spherical shapes. In addition, the surface modified member, as described above, may be partially distributed on the surface of the laminate 1000, and may also be distributed on at least one region in a film shape. That is, the oxide particles are distributed in island shapes on the surface of the laminate, so that the surface modified member may be formed. That is, oxides in a crystalline state or in a non-crystalline state may be distributed so as to be spaced apart from each other on the surface of the laminate 1000, and thus, at least a portion of the surface of the laminate 1000 may be exposed. In addition, the oxides of the surface modified member may be formed in films in at least one region such that at least two or more are connected, and may be formed in island shapes in at least a portion. That is, at least two or more oxide particles may be coagulated or adjacent oxide particles may be connected to form a film shape. However, even when the oxides are present in a particle state or two or more particles are coagulated or connected, at least a portion of the surface of the laminate 1000 may be exposed to the outside by the surface modified member.

At this point, the total area of the surface modified member may be, for example, approximately 5% to 90% of the entire surface area of the laminate 1000. According to the area of the surface modified member, the plating spread phenomenon on the surface of the laminate 1000 may be controlled, but when too much surface modified member is formed, contact between the conductive pattern and the external electrodes 4000 inside the laminate 1000 may be difficult. That is, when the surface modified member is formed in an amount of approximately 5% of the surface area of the laminate 1000, control of the plating spread phenomenon is not easy, and when formed to exceed approximately 90%, the conductive pattern inside the laminate 1000 and the external electrodes 4000 may not come into contact with each other. Thus, it is desirable to form the surface modified member in an area in which the plating spread phenomenon may be controlled and the conductive inside the laminate 1000 and the external electrodes 4000 may come into contact with each other. To this end, the surface modified member may be formed in an area of approximately 10% to 90% of the surface area of the laminate 1000, and favorably, formed in an area of approximately 30% to 70%, and more favorably, formed in an area of approximately 40% to 50%. In this case, the outer surface area of the laminate 1000 may be the outer surface of one surface, or may be the outer surface area of the six surface of the laminate which forms a hexahedron. Meanwhile, the surface modified member may be formed in a thickness of at most approximately 10% of the thickness of the laminate 1000. That is, the surface modified member may be formed in a thickness of at approximately 0.01% to 10% of the thickness of the laminate 1000. For example, the surface modified member may be present in a size of approximately 0.1 μm to 50 μm, and accordingly, the surface modified member may be formed in a thickness of approximately 0.1 μm to 50 μm form the surface of the laminate 1000. That is, the surface modified member may be formed in a thickness of approximately 0.1 μm to 50 μm from the surface of the laminate 1000 excluding the region embedded into the surface of the laminate 1000. Thus, when including the thickness embedded into the laminate 1000, the surface modified member may have the thickness larger than approximately 0.1 μm to 50 μm. when the surface modified member is formed in a thickness of less than approximately 0.01% of the thickness of the laminate 1000, control of the plating spread phenomenon is not easy, and when formed to exceed approximately 10% of the thickness of the laminate 1000, the conductive pattern inside the laminate 1000 and the external electrode may not come into contact with each other. That is, the surface modified member may have various thicknesses according to the material characteristics (conductivity, semi-conductivity, insulating property, magnetism, and the like) of the laminate 1000, and may have various thicknesses according to the size and distributed amount of the oxide particles, and whether the oxide particles are coagulated.

As such, the surface modified member is formed on the surface of the laminate 1000, so that at least two regions having different components may be present on the surface of the laminate 1000. That is, mutually different components may be detected in the region in which the surface modified member has been formed and in the region in which the surface modified member has not been formed. For example, in the region in which the surface modified member has been formed, a component caused by the surface modified member, that is, oxides may be present, and in the region in which the surface modified member has not been formed, a component caused by the laminate 1000, that is, the components of the sheet may be present. As such, before the plating process, the surface modified member is distributed on the surface of the laminate 1000, so that roughness can be applied to the surface of the laminate 1000 to reform the surface. Accordingly, the plating process may be uniformly performed, and thus, the shape of the external electrode 4000 may be controlled. That is, on the surface of the laminate 1000, the resistance of at least one region may be different from those of the other regions, and when a plating process is performed in a state in which resistance is not uniform, uneven growth of a plated layer may be caused. In order to solve such a problem, the surface modified member is formed by distributing oxides in a particle state or a melted state on the surface of the laminate 1000, so that the surface of the laminate 1000 may be reformed and the growth of a plated layer may also be controlled.

Here, at least one of Bi₂O₃, BO₂, B₂O₃, ZnO, Co₃O₄, SiO₂, Al₂O₃, MnO, H₂BO₃, Ca(CO₃)₂, Ca(NO₃)₂, or CaCO₃ may be used for the particle state or melted state oxides for uniformizing surface resistance of the laminate 1000 on the surface of the laminate 1000. Meanwhile, the surface modified member may also be formed on at least one sheet in the laminate 1000. That is, the conductive pattern with various shapes may also be formed on a sheet through a plating process, and the shape of the conductive pattern may be controlled by forming the surface modified member.

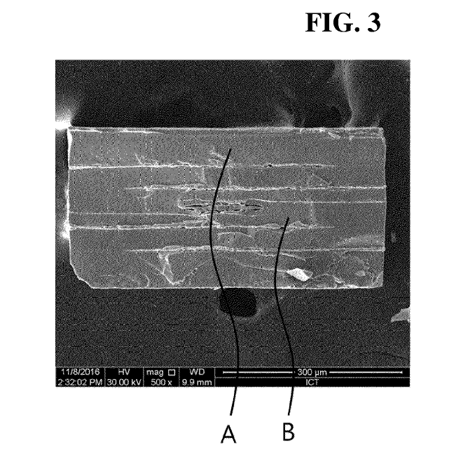

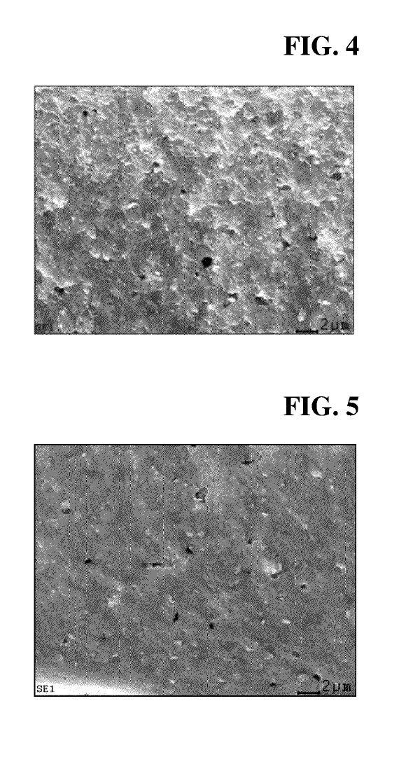

FIG. 3 is a cross-sectional photograph of a complex protection device according to an exemplary embodiment, and FIGS. 4 and 5 are surface photographs of the regions A and B in FIG. 3. That is, FIG. 4 is a surface photograph of an outer peripheral part in the vertical direction, and FIG. 5 is a surface photograph of a central part. Such a complex protection device was formed such that the outermost sheets have lower dielectric constants than the other sheets between in the vertical direction. To this end, the plurality of sheets were formed by mixing, with a predetermined composition ratio, materials including BaTiO₃, NdTiO₃, Bi₂O₃, ZnO, and TiO₂, and the outermost sheets were formed to have a more content of BaTiO₃ and less contents of NdTiO₃ and Bi₂O₃. In addition, the sheets between the outermost sheets were formed to have a more content BaTiO₃ content and a less contents of NdTiO₃ and Bi₂O₃. The remaining components were formed through a slight content adjustment. Component analysis tables of region A and region B of the complex protection device manufactured as such are shown in [Table 1] and [Table 2] respectively.

TABLE 1

| Component | wt % | at % |
|---|---|---|
| O | 6.65 | 31.40 |
| Zn | 4.57 | 5.28 |
| Mg | 0.68 | 2.11 |
| Pt | 9.47 | 3.66 |
| Tc | 6.51 | 5.01 |
| Ba | 24.21 | 13.31 |
| Ti | 15.39 | 24.25 |
| Ce | 0.00 | 0.00 |
| Nd | 19.95 | 10.44 |
| Bi | 12.56 | 4.54 |

TABLE 2

| Component | wt % | at % |
|---|---|---|
| O | 8.84 | 36.90 |
| Zn | 5.41 | 5.53 |
| Mg | 0.88 | 2.41 |
| Pt | 7/96 | 2.73 |
| Tc | 5.17 | 3.52 |
| Ba | 39.69 | 19.31 |
| Ti | 16.87 | 23.53 |
| Ce | 0.00 | 0.00 |
| Nd | 8.50 | 3.94 |
| Bi | 6.68 | 2.14 |

As shown in [Table 1] and [Table 2], it may be understood that outer peripheral regions of the complex protection device in the vertical direction have a less Ba or Ti content than central regions, and a more Nd or Bi content. Accordingly, the dielectric constants of the sheets may be adjusted by adjusting the contents of Ba, Ti, Nd, and Bi, and thus, a complex protection device in accordance with an exemplary embodiment may be implemented in which the dielectric constants of the outermost sheets are low, and the dielectric constants of the remaining sheets therebetween are high.

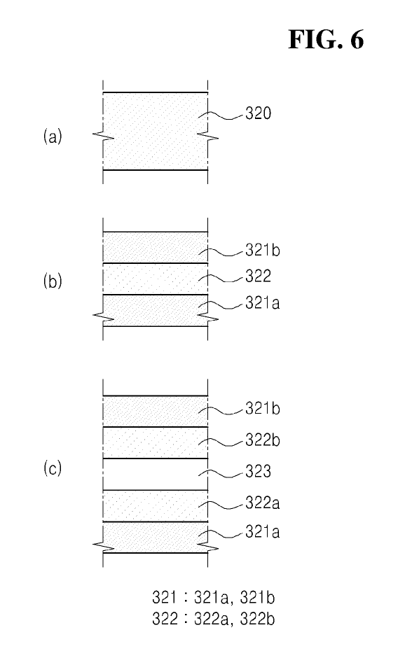

Meanwhile, in the complex protection device in accordance with an exemplary embodiment, the protective layer 320 may be formed in various forms, and such various embodiments of the protective layer 320 are shown in FIGS. 6 to 8.

FIG. 6 is a schematic cross-sectional view of a protective layer 320 of a complex protection device in accordance with a first exemplary embodiment. That is, the protective layer 320 may be formed such that the thickness of at least one region is lower than or larger than the other regions, and FIG. 6 are an enlarged schematic cross-sectional view of a protective layer 320 of some regions of the protective layer 320.

As shown in (a) of FIG. 6, the protective layer 320 may be formed of insulating materials. In this case, porous insulating materials including a plurality of pores (not shown) may be used for the insulating materials. That is, a plurality of pores (not shown) may be formed in the protective layer 320. An overvoltage such as an ESD may be more easily bypassed by forming pores. In addition, the protective layer 320 may be formed by mixing a conductive material and an insulating material. For example, the protective layer 320 may be formed by mixing a conductive ceramic and insulating ceramic. In this case, the protective layer 320 may be formed by mixing the conductive ceramic and the insulating ceramic with a mixing ratio of, for example, approximately 10:90 to approximately 90:10. The more the mixing ratio of the insulating ceramic, the higher a discharge start voltage, and the more the mixing ratio of the conductive ceramic, the lower the discharge start voltage. Accordingly, the mixing ratio of the conductive ceramic and the insulating ceramic may be adjusted so that a predetermined discharge start voltage may be obtained.

In addition, the protective layer 320 may be formed in a predetermined laminated structure by laminating a conductive layer and an insulating layer. That is, the protective layer 320 may be formed by laminating the conductive layer and the insulating layer at least once so that the conductive layer and the insulating layer are divided. For example, the protective layer 320 may be formed in a two-layer structure by laminating the conductive layer and the insulating layer, and a three-layer structure by laminating the conductive layer, the insulating layer, and the conductive layer. In addition, the conductive layers 321 (321a and 321b) and the insulating layer 322 are laminated multiple times so as to be formed in a laminated structure of three layers or more. For example, as shown in (b) of FIG. 6, the protective layer 320 may be formed in which a first conductive layer 321a, an insulating layer 322, and a second conductive layer 321b are laminated. Meanwhile, when the conductive layer and the insulating layer are laminated multiple times, the conductive layer may be positioned on the uppermost layer and the lowermost layer. In this case, a plurality of pores (not shown) may be formed in at least a portion of the conductive layer 321 and the insulating layer 322. For example, since the insulating layer 322 formed between the conductive layers 321 is formed in a porous structure, a plurality of pores may be formed inside the insulating layer 322.

In addition, the protective layer 320 may further be provided with a void in a predetermined region. For example, the void may be formed between layers in which a conductive material and an insulating material are mixed, and the void may also be formed between the conductive layer and the insulating layer. That is, a first mixed layer of a conductive material and an insulating material, a void, and a second mixed layer may be laminated and formed, or a conductive layer, a void, and an insulating layer may also be laminated and formed. For example, as shown in (c) of FIG. 6, the protective layer 320 may be formed by laminating a first conductive layer 321a, a first insulating layer 322a, a void 323, a second insulating layer 322b, and a second conductive layer 321b. That is, the insulating layers 322 (322a and 322b) are formed between the conductive layers 321 (321a and 321b), and the void 323 may be formed between the insulting layers 322. Of course, the protective layer 320 may also be formed by repeatedly laminating the conductive layer, the insulating layer, and the voids. Meanwhile, when the conductive layer 321, the insulating layer 322, and the void 323 are laminated, the thicknesses of all these may be the same, or the thickness of at least any one may be smaller than those of the others. For example, the void 323 may be thinner than the conductive layer 321 and the insulating layer 322. In addition, the conductive layer 321 may be formed in the same thickness as the insulating layer 322, or be formed to be thicker or thinner than the insulating layer 322. Meanwhile, the void 323 may be formed by performing a firing process after filling a polymer material and removing the polymer material. For example, the conductive layer, the insulating layer and the void may be formed by performing a firing process after filling a first polymer material including conductive ceramic, a second polymer material including insulating ceramic, and a third polymer material which does not include conductive ceramic, insulating ceramic, and the like, and removing the polymer material. Meanwhile, the void 323 may also be formed such that layers are not divided. For example, the insulating layer 322 is formed between the conductive layers 321a and 321b, and the void 323 may be formed by the connection of a plurality of pores are connected in the vertical direction or in the horizontal direction. That is, the void 323 may be formed as a plurality of pores inside the insulating layer 322. Of course, the void 323 may also be formed in the conductive layer 321 by the plurality of pores.

Meanwhile, the conductive layer 321 used for the protective layer 320 may have predetermined resistance and allow current to flow therethrough. For example, the conductive layer 321 may be a resistive body having several ohms to several hundred ohms. When an overvoltage such as an ESD is introduced, the conductive layer 321 lowers an energy level and prevents the occurrence of structural destruction of a complex protection device caused by the overvoltage. That is, the conductive layer 321 functions as a heat sink which converts electrical energy to thermal energy. This conductive layer 321 may be formed by using conductive ceramic, and a mixture including one or more of La, Ni, Co, Cu, Zn, Ru, Ag, Pd, Pt, W, Fe or Bi may be used for the conductive ceramic. In addition, the conductive layer 321 may be formed in a thickness of approximately 1 μm to 50 μm. That is, when the conductive layer 321 is formed as a plurality of layers, the sum of the all the thicknesses may be formed to be approximately 1 μm to 50 μm.

In addition, the insulating layer 322 used for the protective layer 320 may be formed of a discharge inducing material, and may function as an electrical barrier having a porous structure. This insulating layer 322 may be formed of insulating ceramic, and a ferroelectric material having a dielectric constant of approximately 50 to 50,000 may be used for the insulating ceramic. For example, the insulating ceramic may be formed by using a mixture including dielectric material powder such as MLCC and one or more among ZrO, ZnO, BaTiO₃, Nd₂O₅, BaCO₃, TiO₂, Nd, Bi, Zn or Al₂O₃. This insulating layer 322 may be formed in a porous structure in which pores having the sizes of approximately 1 μm to 5 μm are formed in plurality and formed in a porosity of approximately 30% to 80%. In this case, the shortest distance between the pores may be approximately 1 μm to 5 μm. That is, the insulating layer 322 is formed of an electrical insulating material through which current may not flow, but since the pores are formed, current may flow through the pores. At this point, the larger the sizes of the pores or the porosity, the lower the discharge start voltage may be, and conversely, the smaller the sizes of the pores or the porosity, the higher the discharge start voltage may be. However, when the sizes of the pores exceed approximately 5 μm, or the porosity exceeds approximately 80%, keeping the shape of the protective layer 320 may be difficult. Accordingly, the pore size and the porosity of the insulating layer 322 may be adjusted so as to adjust the discharge start voltage while maintaining the shape of the protective layer 320. Meanwhile, when the protective layer 320 is formed of a material mixture of an insulating material and a conductive material, insulating ceramic having fine pores and porosity may be used for the insulating material. In addition, the insulating material 322 may be formed to have a lower resistance than those of the sheets by means of fine pores, and a partial discharge may be performed through the fine pores. That is, the fine ores are formed in the insulating layer 322 and a partial discharge is performed through the fine pores. This insulating layer 322 may be formed in a thickness of approximately 1 μm to 50 μm. That is, when the insulating layer 322 is formed as a plurality of layers, the sum of the all the thicknesses may be formed to be approximately 1 μm to 50 μm.

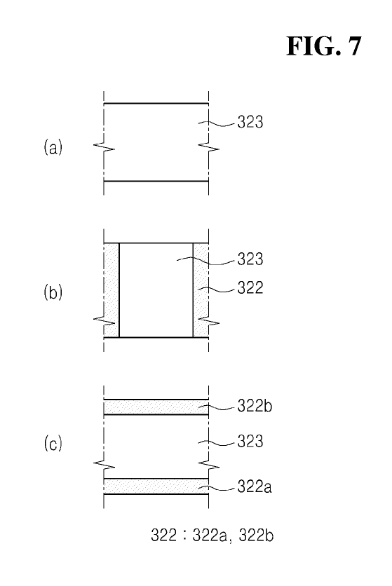

FIG. 7 is a schematic cross-sectional view of a protective layer 320 of a complex protection device in accordance with a second exemplary embodiment. That is, the protective layer 320 may include a void 323 as shown in (a) of FIG. 7. That is, in the protective layer 320, the void 323 may be formed without filling an overvoltage protection material into an opening formed by passing through a sheet. In addition, in the protective layer 320, a porous insulating material may be formed in at least a region of the through-hole. That is, as shown in (b) of FIG. 7, the insulating layer 322 may be formed by applying a porous insulating material on a side wall of the through-hole, and as shown in (c) of FIG. 7, the insulating layers 322 (322a and 322b) may be formed in at least one of upper and lower sides of the through-hole.

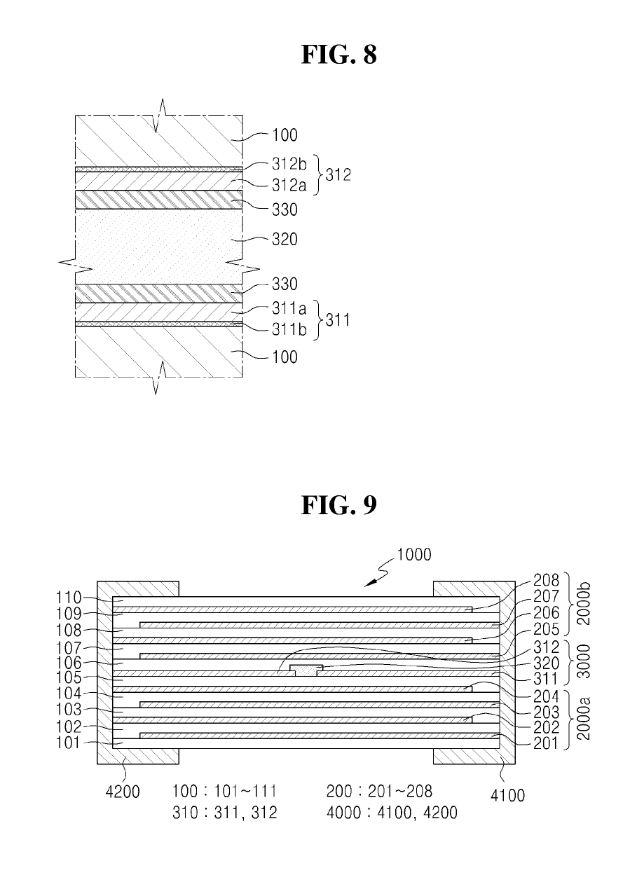

FIG. 8 is a schematic cross-sectional view of the protective layer 320 in accordance with a third exemplary embodiment of the complex device, and as shown in FIG. 8, the protective layer 320 may further include a discharge inducing layer 330 formed between the discharge electrodes 310 (3111 and 312) and the protective layer 320. That is, the discharge inducing layer 330 may further be formed between the discharge electrode 310 and the protective layer 320. At this point, the discharge electrode 310 may include conductive layers 311a and 312a and porous insulating layers 311b and 312b formed on at least one surface of the conductive layers 311a and 312a. Of course, the discharge electrode 310 may also be a conductive layer having a surface without a porous insulating layer formed thereon.

This discharge inducing layer 330 may be formed when forming the protective layer 320 using a porous insulating material. In this case, the discharge inducing layer 330 may be formed as a dielectric layer having a higher density than the protective layer 320. That is, the discharge inducing layer 330 may be formed of a conductive material, and also be formed of an insulating material. For example, when the protective layer 320 is formed by using porous ZrO, and the internal electrode 200 is formed by using Al, an AlZrO discharge inducing layer 330 may be formed between the protective layer 320 and the discharge electrode 310. Meanwhile, TiO may be used instead of ZrO for the protective layer 320, and in this case, the discharge inducing layer 330 may be formed of TiAlO. That is, the discharge inducing layer 330 may be formed by a reaction of the discharge electrode 310 and the protective layer 320. Of course, the discharge inducing layer 330 may be formed by a further reaction of a sheet material. In this case, the discharge inducing layer 330 may be formed by the reaction of an internal electrode material (for example, Al), a protective part material (for example, ZrO), and a sheet material (for example, BaTiO₃). In addition, the discharge inducing layer 330 may be formed by a reaction with the sheet material. That is, the discharge inducing layer 330 may be formed through a reaction of the protective layer 320 and the sheets in a region where the protective layer 320 comes into contact with the sheets. Accordingly, the discharge inducing layer 330 may be formed to surround the protective layer 320. At this point, the discharge inducing layer 330 between the protective layer 320 and the discharge electrode 310 and the discharge inducing layer 330 between the protective layer 320 and the sheets may have mutually different compositions. Meanwhile, the discharge inducing layer 330 may be formed by removing at least one region thereof, and may also be formed so that the thickness of at least one region may be different from those of the others. That is, the discharge inducing layer 330 may be discontinuously formed by removing at least one region thereof, and may also be irregularly formed so that the thickness of at least one region may be different from those of the others. This discharge inducing layer 330 may be formed during a firing process. That is, the discharge inducing layer 330 may be formed between the discharge electrode 310 and the protective layer 320 such that a discharge electrode material, an ESD protection material and the like are mutually diffused during a firing process at a predetermined temperature. Meanwhile, the discharge inducing layer 330 may be formed in a thickness of approximately 10% to 70% of the thickness of the protective layer 320. That is, the thickness of a portion of the protective layer 320 may be changed into the discharge inducing layer 330. Accordingly, the discharge inducing layer 330 may be formed to be thinner than the protective layer 320, and may be formed in a thickness larger than, equal to, or smaller than that of the discharge electrode 310. The level of discharge energy of the ESD voltage induced to the protective layer 320 may be lowered by the discharge inducing layer 330. Accordingly, the ESD voltage may be more easily discharged, and thus, the discharge efficiency may be improved. In addition, the diffusion of foreign substances to the protective layer 320 may be prevented by forming the discharge inducing layer 330. That is, the diffusion of the sheet material and the internal electrode material to the protective layer 320 may be prevented, and external diffusion of the overvoltage protection material may be prevented. Thus, the discharge inducing layer 330 may be used as a diffusion barrier, and thus, the destruction of the protective layer 320 may be prevented. Meanwhile, a conductive material may further be included in the protective layer 320, and in this case, the conductive material may be coated with insulating ceramic. For example, as described by using (a) of FIG. 6, when the protective layer 320 is formed by mixing a porous insulating material and a conductive material, the conductive material may be coated by using NiO, CuO, WO or the like. Accordingly, the conductive material may be used as a material for the protective layer 320 together with the porous insulating material. In addition, when a conductive material is further used for the protective layer 320 aside from the porous insulating material, as shown in, for example, (b) of FIG. 6 and (c) of FI. 6, when the insulating layer 322 is formed between two conductive layers 321a and 321b, the discharge inducing layer 330 may be formed between the conductive layer 321 and the insulating layer 322. Meanwhile, the discharge electrode 310 may be formed in a shape from which a portion of regions are removed. That is, the discharge electrode 310 is partially removed, and the discharge inducing layer 330 may be formed in the removed region. However, even though being partially removed, the discharge electrode 310 maintain the totally connected shape on a plane, and thus, the electrical characteristic is not degraded.

The discharge electrode 310 may be formed of a metal or a metal alloy having a surface on which an insulating layer is formed. That is, the discharge electrode 310 may include conductive layers 311a and 312a and porous insulating layers 311b and 312b formed on at least one surface of the conductive layers 311a and 312a. At this point, the porous insulating layers 311b and 312b may be formed on at least one surface of the discharge electrode 310. That is, the discharge electrode may be formed only on one surface which is not in contact with the protective layer 320 and the other surface which is in contact with the protective layer 320, and may also be formed on one surface which is not contact with the protective layer 320 and the other surface which is in contact with the protective layer 320. In addition, the porous insulating layers 311b and 312b may be entirely formed on at least one surface of the conductive layers 311a and 312a, or may also be formed only on at least a portion thereof. In addition, the porous insulating layers 311b and 312b may be formed such that at least a portion thereof is removed or be formed in a small thickness. That is, the porous insulating layers 311b and 312b may not be formed on at least one region of the conductive layers 311a and 312a, and may also be formed such that the thickness of at least one region is smaller than or larger than the thicknesses of the other region. In this discharge electrode 310, an oxide film may be formed on the surface thereof during firing and the inside thereof may be formed of Al that keeps conductivity. That is, when forming Al on a sheet, Al comes into contact with air, and the surface of Al is oxidized in a firing process, so that Al₂O₃ is formed and the internal portion maintains Al as it is. Thus, the internal electrode 200 may be formed of Also as to have a surface coated with Al₂O₃ which is a thin porous insulating layer. Of course, aside from Al, various metals may be used in which an insulating layer, favorably a porous insulating layer is formed on a surface.

Meanwhile, in an exemplary embodiment, the protective layer 320 was formed by embedding or applying an overvoltage protection material into a through-hole formed in the sheet 106. However, the protective layer 320 may be formed on a predetermined region of the sheets and the discharge electrodes 310 may be formed so as to be each in contact with the respective protective layer 320. That is, as shown in a cross-sectional view of another exemplary embodiment of FIG. 9, two discharge electrodes 311 and 312 are formed to be horizontally spaced apart a predetermined distance from each other, and a protective layer 320 may be formed between the two discharge electrodes 311 and 312.

A protection part 3000 may include at least two discharge electrodes 311 and 312 formed on the same plane to be spaced apart from each other and at least one ESD protective layer 320 provided between the two discharge electrodes 311 and 312. That is, the two discharge electrodes 311 and 312 may be provided so as to be mutually spaced apart in the direction in which an external electrode 4000 is formed, that is, in the X-direction, and two or more discharge electrodes (not shown) may further be provided in a direction perpendicular thereto. Accordingly, at least one discharge electrode may be formed in the direction perpendicular to the direction in which the external electrode 4000 is formed, and at least one discharge electrode may be formed so as to be mutually spaced apart a predetermined distance. For example, as shown in FIG. 9, the protection part 3000 may include: a fifth sheet 105; first and second discharge electrode 311 and 312 formed on the fifth sheet 105; and a protective layer 320 formed on the fifth sheet 105. Here, the protective layer 320 may be formed to be at least partially connected to the first and second discharge electrodes 311 and 312. The first discharge electrode 311 is formed on the fifth sheet 105 so as to be connected to an external electrode 4100, and connected such that an end portion thereof is connected to the protective layer 320. The second discharge electrode 312 is formed on the fifth sheet 105 so as to be connected to an external electrode 4200 and to be spaced apart from the first discharge electrode 311, and formed such that an end portion thereof is connected to the protective layer 320. The protective layer 320 may be formed on a predetermined region of the fifth sheet 105, for example, may be formed on a central portion so as to be connected to the first and second discharge electrodes 311 and 312. At this point, the protective layer 320 may be formed to be at least partially overlap the first and second discharge electrodes 311 and 312. The protective layer 320 may be formed on the fifth sheet 105 exposed between the first and second discharge electrodes 311 and 312, and also be connected to the side surfaces of the first and second discharge electrodes 311 and 312. However, in this case, since the protective layer 320 may not be in contact with the first and second discharge electrodes 311 and 312 and be spaced apart therefrom, an ESD protection layer 320 may favorably be formed so as to overlap the first and second discharge electrodes 311 and 312. Even when the discharge electrode 310 and the protective layer 320 are formed in the same plane as such, the external electrode 4000 may be formed so as to at least partially overlap an internal electrode 200, and the outermost sheets, that is, first and 10th sheets 101 and 110 may be formed therebetween so as to have dielectric constants lower than those of the remaining sheets, that is, second to ninth sheets 102 to 109.

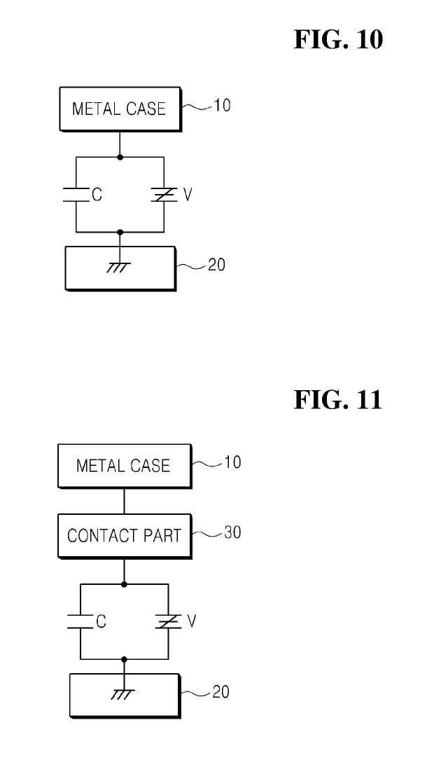

The above-mentioned complex protection devices in accordance with exemplary embodiments may be provided between a metal case 10 and an internal circuit 20 of an electronic apparatus as shown in FIG. 10. That is, any one of the external electrodes 4000 may be connected to a ground terminal, and the other may be connected to the metal case 10 of the electronic apparatus. In this case, the ground terminal may be provided inside the internal circuit 20. For example, a first external electrode 4100 may be connected to the ground terminal, and a second external electrode 4200 may be connected to the metal case 10. In addition, as shown in FIG. 11, a contact part 30 using a conductive member such as a contactor, a conductive gasket or the like may further be provided between a second external electrode 4200 and a metal case 10. Accordingly, a shock voltage transmitted from a ground terminal of an internal circuit 20 may be blocked, and an overvoltage such as an ESD applied from the outside to the internal circuit may be bypassed to the ground terminal. That is, in the complex protection device of an exemplary embodiment, current may not flow between the external electrodes 4000 at the rated voltage and a shock voltage, and current flows at an ESD voltage through a protective layer 320, an overvoltage is bypassed to a ground terminal. Meanwhile, the complex protection device may have a discharge start voltage higher than the rated voltage and lower than the ESD voltage. For example, the complex protection voltage may have the rated voltage of approximately 100V to 240V, the shock voltage may be the same or higher than the operation voltage of a circuit, and the ESD voltage generated by external electrostatic electricity or the like may be higher than the shock voltage. In addition, a communication signal from the outside, that is, an AC frequency may be transmitted to the internal circuit 20 through a capacitor formed between internal electrodes 200. Accordingly, a communication signal from the outside may be applied even when the metal case 10 is used as an antenna without providing a separate antenna. Consequently, the complex protection device in accordance with an exemplary embodiment may block a shock voltage, bypass the ESD voltage to the ground terminal, and apply a communication signal to the internal circuit.

In addition, in the complex protection device in accordance with an exemplary embodiment, a plurality of sheets having high voltage-resistant characteristic are laminated to form a main body 100, and thus, an insulating resistive state may be maintained so that a leak current may not flow when a shock voltage of, for example, approximately 310 V is introduced toward the metal case 10 in the internal circuit 20 due to a defective charger. In addition, the protective layer 320 may also bypass an overvoltage when the overvoltage is introduced to the internal circuit 20 from the metal case 10, and maintain a high insulation resistive state without breaking the device. That is, the protective layer is formed in a porous structure, and includes a porous insulating material that causes current to flow through fine pores, and further includes a conductive material which lowers an energy level and converts electrical energy into thermal energy, and may thus protect a circuit by bypassing an overvoltage introduced from the outside. Accordingly, the complex protection device is not electrically broken down even by an overvoltage, may thereby be provided in the electronic apparatus provided with the metal case 10, and may continuously prevent a shock voltage generated in a defective charger from being transmitted to a user through the metal case 10 of the electronic apparatus. Meanwhile, a general multilayer capacitance circuit (MLCC) is an element which protects a shock voltage but is weak to an ESD, and thus, when applying repeated ESD, a spark is generated at a leak point due to charging, and an element breakage phenomenon may occur. However, in an exemplary embodiment, the protective layer 320 is formed which includes a porous insulating material between the internal electrodes 200, and an overvoltage is bypassed through the protective layer 320, and thus, at least a portion of the main body 100 is not broken.

In addition, the external electrode 4000 and the internal electrode 200 are caused to overlap each other, so that a predetermined parasitic capacitance may be generated between the external electrode 4000 and the internal electrode 200, and the overlapping area between the external electrode 4000 and the internal electrode 200 are adjusted, so that the capacitance of the complex protection device may be adjusted. However, since the capacitance of the complex protection device affects the performance of an antenna inside the electronic apparatus, a sheet 100 having a high dielectric constant is used to maintain the distribution of the capacitance of the complex protection device within approximately 5%. Thus, the higher the dielectric constant of the sheet 100, the greater the influence of the parasitic capacitance between the internal electrode 200 and the external electrode 4000 may be. However, since the dielectric constants of the sheets positioned outermost are lower than those of the remaining sheets therebetween, the influence of the parasitic capacitance between the internal electrode 200 and the external electrode 4000 may be reduced.

In exemplary embodiments, complex protection devices have been exemplarily described which are provided in electronic apparatuses of smartphones, protect the electronic apparatuses from an overvoltage such as an ESD applied from the outside, and protect a user by blocking leak current form the insides of the electronic apparatuses, and thereby protect the a user. However, the complex protection devices of exemplary embodiments may be provided in various electronic apparatuses aside from smartphones, and carry out at least two protection functions.

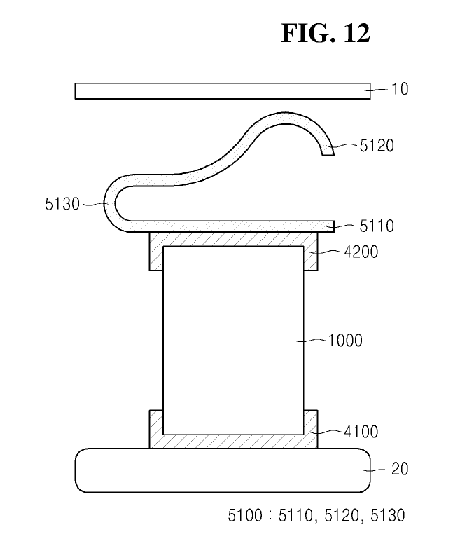

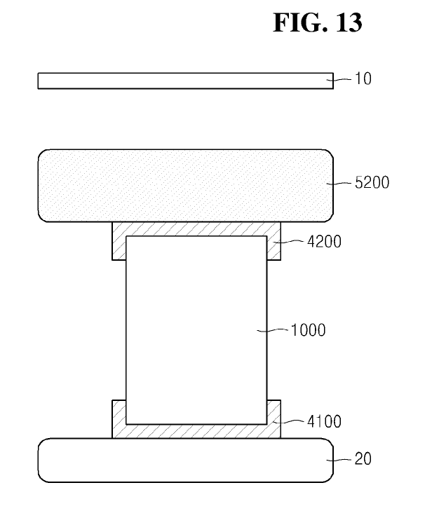

Meanwhile, as shown in FIG. 11, a contact part 30 which comes into electrical contact with a metal case 10 and has elasticity may be provided between the metal case 10 and a complex protection device. That is, the contact part 30 and the complex protection device in accordance with an exemplary embodiment may be provided between the metal case 10 and an internal circuit 20 of an electronic apparatus. The contact part 30 may be formed of a material which has elasticity so that when an external force is applied from the outside of the electronic apparatus, a shock thereof may be mitigated, and which includes a conductive material. This contact part 30 may have a clip shape as shown in FIG. 12, or may also be a conductive gasket as shown in FIG. 13. In addition, at least a portion of the contact part 30 may be mounted on an internal circuit 20, for example, on a PCB. Complex protection devices including the contact parts 30 will be described as follows using FIGS. 12 and 13.

FIGS. 12 and 13 are cross-sectional views of complex protection devices in accordance with one exemplary embodiment and modified examples, and the complex protection devices are each provided between a metal case 10 and an internal circuit 20, and a clip-shaped contact part 5100 or a contact part 5200 using a conductive material layer may be provided on a second external electrode 4200 of the complex protection device as shown respectively in FIGS. 12 and 13. The contact parts 5100 and 5200 may be formed of a material which has elasticity so that when an external force is applied from the outside of the electronic apparatus, a shock thereof may be mitigated, and which includes a conductive material. Meanwhile, a first external electrode 4100 of the complex protection device may be provided to be in contact with the internal circuit 20, and a metal layer made of stainless steel or the like may further be provided between the internal circuit 20 and the first external electrode 4100.

As shown in FIG. 12, the contact part 5100 may have a clip shape. The clip-shaped contact part 5100 may include: a support part 5110 provided on a complex protection device; a contact part 5120 provided over the support part 5110, positioned facing a conductive body such as a metal case, and has at least a portion which may be in contact with the conductive body; and a connection part 5130 provided between the support part 5110 and one side of the contact part 5120, configured to connect these, and having elasticity. Here, the connection part 5130 is formed to connect one end of the support part 5110 and one end of the contact part 5120, and may be formed to have a curvature. That is, the connection part 5130 has elasticity so as to be pressed in the direction in which a circuit board 20 is positioned when pressed by an external force, and to be restored when the external force is released. Accordingly, in the contact part 5100, at least the connection part 5130 may be formed of a metal material having elasticity.

In addition, aside from the clip shape having conductivity and elasticity, the contact part of an exemplary embodiment may include conductive rubber, conductive silicone, an elastic body in which a conductive wire is inserted, and a gasket having a surface coated or joined by a conductor. That is, as shown in FIG. 13, the contact part 5200 may include a conductive material layer. For example, in case of a conductive gasket, the inside thereof may be formed of a non-conductive elastic body, and the outside thereof may be coated with a conductive material. Although not shown, the conductive gasket may include: an insulating elastic core in which a through-hole is formed; and a conductive layer formed to surround the insulating elastic core. The insulating elastic core has a tube shape in which the through-hole is formed, and thus may be formed to have a cross-section with an approximate rectangular or circular shape, but the exemplary embodiments are not limited thereto, and may be formed in various shapes. For example, the insulating elastic core may have no through-hole formed therein. This insulating elastic core may be formed of silicone, elastic rubber or the like. The conductive layer may be formed to surround the insulating elastic core. This conductive layer may be formed of at least one metal layer, and for example, may be formed of gold, silver, copper, etc. Meanwhile, without forming the conductive layer, conductive powder may also be mixed to the elastic core.

The present invention may, however, be embodied in different forms and should not be construed as limited to the embodiments set forth herein. That is, the above embodiments are provided so that this disclosure will be thorough and complete, and will fully convey the scope of the present disclosure to those skilled in the art, and the scope of the present disclosure should be understood by the scopes of claims of the present application.

1. A complex protection device comprising:
a laminate in which a plurality of sheets are laminated;
a plurality of internal electrodes formed inside the laminate;
an overvoltage protection part formed on at least a portion of the sheets; and
external electrodes provided outside the laminate and connected to the internal electrodes and the overvoltage protection part,
wherein at least a portion of the plurality of sheets has a dielectric constant different from other sheets.

2. The complex protection device of claim 1, wherein the overvoltage protection part comprises: at least two discharge electrodes; and at least one overvoltage protection layer provided between the discharge electrodes.

3. The complex protection device of claim 2, wherein the overvoltage protection layer comprises at least one among a porous insulating material, a conductive material, and a void.

4. The complex protection device of claim 2, wherein the discharge electrodes and the internal electrodes adjacent thereto are connected to a same external electrode.

5. The complex protection device of claim 2, wherein the discharge electrodes and the internal electrodes adjacent thereto are connected to another external electrode.

6. The complex protection device of claim 1, wherein at least one of the plurality of internal electrodes is formed in a length different form the other internal electrodes.

7. The complex protection device of claim 1, wherein the external electrodes extend to at least any one of a lowermost layer and an uppermost layer of the laminate and partially overlap outermost internal electrodes.

8. The complex protection device of claim 7, wherein the outermost internal electrodes are each formed such that a region overlapping the external electrode is formed to have a width larger than remaining regions.

9. The complex protection device of claim 6, wherein dielectric constants of sheets provided between the external electrodes and the outermost internal electrodes are lower than dielectric constants of other sheets.

10. The complex protection device of claim 9, wherein the dielectric constants of the sheets provided between the external electrodes and the outermost internal electrodes are at most approximately 100 and the dielectric constants of other sheets are at least approximately 500.

11. The complex protection device of claim 9, wherein the sheets provided between the external electrodes and the outermost internal electrodes each have a lower Ba or Ti content than remaining sheets.

12. The complex protection device of claim 9, wherein the sheets provided between the external electrodes and the outermost internal electrodes each have a higher Nd or Bi content than the remaining sheets.

13. An electronic apparatus comprising a complex protection device provided between a conductor contactable to a user and an internal circuit and configured to block a shock voltage and bypass an overvoltage,
wherein the complex protection device comprises the complex protection device of claim 1.
